(19) United States
(12) Patent Application Publication
(10) Pub. No.: US 2024/0215408 A1
(43) Pub. Date: Jun. 27, 2024

(54) ORGANIC LIGHT EMITTING DIODE DISPLAY DEVICE INCLUDING PHASE RETARDATION PATTERN

(71) Applicant: LG Display Co., Ltd., Seoul (KR)

(72) Inventors: Da-In SONG, Paju-si (KR); Hyun-Joo KIM, Paju-si (KR)

(73) Assignee: LG Display Co., Ltd., Seoul (KR)

(21) Appl. No.: 18/243,889

(22) Filed: Sep. 8, 2023

(30) Foreign Application Priority Data
Dec. 23, 2022 (KR) 10-2022-0183517

(51) Int. Cl. H10K 59/80; H10K 59/121

(52) U.S. Cl. CPC H10K 59/879; H10K 59/1213

(57) ABSTRACT

An organic light emitting diode display device can include a substrate having a subpixel, a phase retardation pattern in the subpixel on the substrate, a planarizing layer on the phase retardation pattern, an overcoat layer on the planarizing layer, a top surface of the overcoat layer having a plurality of microlenses, and a light emitting diode on the plurality of microlenses. The plurality of microlenses includes first and second unit cells. The phase retardation pattern is disposed to correspond to the first unit cell.

### CROSS-REFERENCE TO RELATED APPLICATIONS

The present application claims priority to Korean Patent Application No. 10-2022-0183517, filed in Republic of Korea on Dec. 23, 2022, the entire contents of which is hereby expressly incorporated by reference into the present application.

### BACKGROUND

### Field

The present disclosure relates to a display device, and more particularly, to an organic light emitting diode display device where an interference fringe of a microlens is removed due to a phase retardation pattern.

### Discussion of the Related Art

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

Among the various flat panel display devices, an organic light emitting diode (OLED) display device is an self-emissive type device that does not include a backlight unit used in a non-self-emissive type device such as a liquid crystal display (LCD) device. As a result, the OLED display device has a light weight and a thin profile.

Further, the OLED display device has advantages in a viewing angle, a contrast ratio and a power consumption as compared with the LED device. The OLED display device is driven with a direct current (DC) low voltage and has a relatively rapid response speed. Since inner elements of the OLED display device have a solid state, the OLED display device has a relatively strong resistance to an external impact and has a relatively wide temperature range.

In an OLED display device, most of a light generated in an emitting layer can be lost while the light is emitted to an exterior through various elements, and the light emitted to the exterior can be only about 20% of the light generated in the emitting layer. Since the amount of the light emitted from the emitting layer can increase according to the amount of the current applied to the light emitting diode, the luminance of the light can be increased by applying a larger current to the light emitting diode. However, in such a case, a power consumption can increase and a life time of the OLED display device can be reduced.

### SUMMARY OF THE DISCLOSURE

Accordingly, the present disclosure is directed to a display device that substantially obviates one or more of the problems due to limitations and disadvantages of the related art.

An object of the present disclosure is to provide an organic light emitting diode display device where interference fringes generated by first and second unit cells of a microlens array are offset due to a phase retardation pattern to correspond to one of the first and second unit cells and deterioration such as a rainbow stain is minimized.

Another object of the present disclosure is to provide an organic light emitting diode display device where deterioration such as a rainbow stain is minimized in a viewing angle range equal to or smaller than about 70 degrees for an entire wavelength range, by determining a gap length between first and second unit cells of a microlens array smaller than a coherence length and by disposing a phase retardation pattern to correspond to one of the first and second unit cells.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, an organic light emitting diode display device includes: a substrate having a subpixel; a phase retardation pattern in the subpixel on the substrate; a planarizing layer on the phase retardation pattern; an overcoat layer on the planarizing layer, a top surface of the overcoat layer having a plurality of microlenses; and a light emitting diode on the plurality of microlenses, wherein the plurality of microlenses include first and second unit cells, and wherein the phase retardation pattern is disposed to correspond to the first unit cell.

In another aspect, an organic light emitting diode display device can include a plurality of subpixels, each of the plurality of subpixels comprises an emission area and a non-emission area surrounding the emission area, where each of the plurality of subpixels includes: a substrate; a phase retardation pattern disposed on the substrate and in the emission area; a plurality of microlenses disposed on the phase retardation pattern and in the emission area; and a light emitting diode disposed on the plurality of microlenses and in the emission area, wherein the plurality of microlenses includes first and second unit cells adjacent to each other, and wherein the phase retardation pattern is disposed to only corresponds to one of the first unit cell and the second unit cell.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing an organic light emitting diode display device according to a first embodiment of the present disclosure;

FIG. 2 is a cross-sectional view showing an organic light emitting diode display device according to the first embodiment of the present disclosure;

FIG. 3 is a plan view showing an emission area of an organic light emitting diode display device according to the first embodiment of the present disclosure;

FIG. 4 is a cross-sectional view showing a path of an external light in an organic light emitting diode display device according to the first embodiment of the present disclosure;

FIG. 5A is a view showing a constructive interference and a destructive interference of a unit cell of an organic light emitting diode display device according to the first embodiment of the present disclosure;

FIG. 5B is a view showing an interference fringe of a unit cell of an organic light emitting diode display device according to the first embodiment of the present disclosure;

FIG. 6 is a view showing an interference of lights reflected by first and second unit cells of an organic light emitting diode display device according to the first embodiment of the present disclosure;

FIG. 7A is a view showing a destructive interference of first and second external lights of an organic light emitting diode display device according to the first embodiment of the present disclosure;

FIG. 7B is a view showing a first thickness of a phase retardation pattern for a destructive interference of first and second external lights of an organic light emitting diode display device according to the first embodiment of the present disclosure;

FIG. 8A is a view showing a removal degree of an interference fringe with respect to a gap length between first and second unit cells of an organic light emitting diode display device according to the first embodiment of the present disclosure;

FIG. 8B is a plan view showing a gap length between adjacent first and second unit cells of an organic light emitting diode display device according to the first embodiment of the present disclosure;

FIG. 8C is a view showing a coherence length of an organic light emitting diode display device according to the first embodiment of the present disclosure;

FIG. 9 is a view showing an interference fringe with respect to a wavelength of an organic light emitting diode display device according to the first embodiment of the present disclosure;

FIG. 10 is a plan view showing an emission area of an organic light emitting diode display device according to a second embodiment of the present disclosure;

FIG. 11 is a plan view showing an emission area of an organic light emitting diode display device according to a third embodiment of the present disclosure;

FIG. 12 is a plan view showing an emission area of an organic light emitting diode display device according to a fourth embodiment of the present disclosure;

FIG. 13 is a view showing an interference fringe with respect to a wavelength of an organic light emitting diode display device according to the fourth embodiment of the present disclosure;

FIG. 14 is a plan view showing an emission area of an organic light emitting diode display device according to a fifth embodiment of the present disclosure;

FIG. 15 is a plan view showing an emission area of an organic light emitting diode display device according to a sixth embodiment of the present disclosure;

FIG. 16 is a plan view showing an emission area of an organic light emitting diode display device according to a seventh embodiment of the present disclosure;

FIG. 17 is a plan view showing an emission area of an organic light emitting diode display device according to an eighth embodiment of the present disclosure; and

FIG. 18 is a plan view showing an emission area of an organic light emitting diode display device according to a ninth embodiment of the present disclosure.

### DETAILED DESCRIPTION OF THE EMBODIMENTS

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

Hereinafter, an organic light emitting diode display device according to embodiments of the present disclosure will be described in detail with reference to the accompanying drawings. All the components of each organic light emitting diode display device according to all embodiments of the present disclosure are operatively coupled and configured.

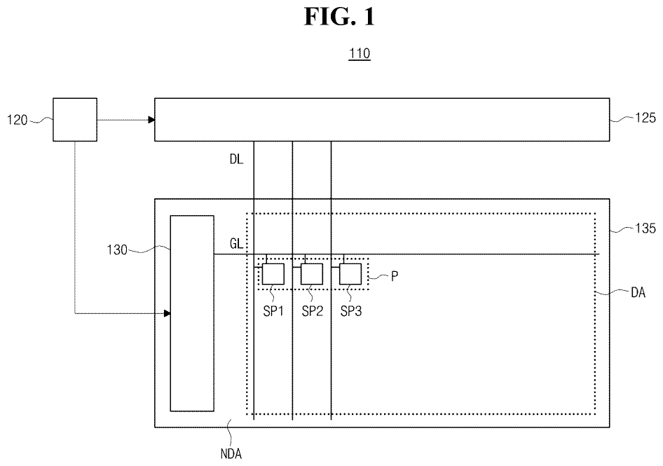

FIG. 1 is a view showing an organic light emitting diode display device according to a first embodiment of the present disclosure.

In FIG. 1, an organic light emitting diode (OLED) display device 110 according to the first embodiment of the present disclosure includes a timing controlling unit 120, a data driving unit 125, a gate driving unit 130 and a display panel 135. The display panel 135 includes a plurality of pixels P each composed of a plurality of sub-pixels.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The image data and the data control signal are transmitted to the data driving unit 125, and the gate control signal is transmitted to the gate driving unit 130.

The data driving unit 125 generates a data signal (a data voltage) using the data control signal and the image data transmitted from the timing controlling unit 120 and transmits the data signal to a data line DL of the display panel 135.

The gate driving unit 130 generates a gate signal (a gate voltage) using the gate control signal transmitted from the timing controlling unit 120 and supplies the gate signal to a gate line GL of the display panel 135. Further, the gate driving unit 130 can generate an emission signal according to a structure of each subpixel SP1, SP2 and SP3 and supply the emission signal to the display panel 135.

The gate driving unit 130 can have a gate in panel (GIP) type to be formed in a non-display area NDA of a substrate of the display panel 135 having the gate line GL, the data line DL and a pixel P.

The display panel 135 includes a display area DA at a central portion thereof and a non-display area NDA surrounding the display area DA. The display panel 135 displays an image using the gate signal and the data signal. For displaying an image, the display panel 135 includes the plurality of pixels P, a plurality of gate lines GL and a plurality of data lines DL in the display area DA.

In an example, each of the plurality of pixels P includes first, second and third subpixels SP1, SP2 and SP3, and the gate line GL and the data line DL cross each other to define the first, second and third subpixels SP1, SP2 and SP3. However, each pixel P can include a different number of sub-pixels generating different colors. Each of the first, second and third subpixels SP1, SP2 and SP3 is connected to the gate line GL and the data line DL.

As an example, each of the first, second and third subpixels SP1, SP2 and SP3 can correspond to one of red, green, blue and white colors, and some of the colors may or may not be repeated in each pixel P.

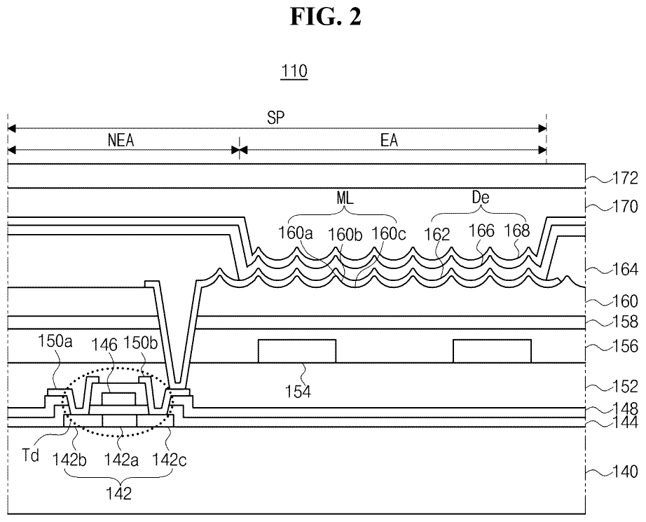

Each of the first, second and third subpixels SP1, SP2 and SP3 can include a plurality of thin film transistors (TFTs) Td (of FIG. 2) such as a switching TFT and a driving TFT, a storage capacitor and a light emitting diode De (of FIG. 2).

FIG. 2 is a cross-sectional view showing an organic light emitting diode display device according to the first embodiment of the present disclosure. The organic light emitting diode (OLED) display device can have a bottom emission type.

In FIG. 2, the OLED display device 110 according to the first embodiment of the present disclosure includes a driving thin film transistor (TFT) Td and a light emitting diode (LED) De in each subpixel SP on a substrate 140.

Each subpixel SP of the OLED display device 110 can further include a switching TFT, a sensing TFT and a storage capacitor. The switching TFT and the sensing TFT can have the same structure as the driving TFT Td.

The substrate 140 includes a plurality of subpixels SP, and each of the plurality of subpixels SP includes an emission area EA where the LED De is disposed and a non-emission area NEA where the driving TFT Td is disposed.

The substrate 140 can be formed of a glass or a plastic such as polyimide.

A semiconductor layer 142 is disposed in the non-emission area NEA on the substrate 140 and includes an active region 142a and a drain region 142b and a source region 142c at both sides of the active region 142a.

The active region 142a can include intrinsic polycrystalline silicon, and the drain region 142b and the source region 142c can include impurity-doped polycrystalline silicon.

In another embodiment, a light shielding layer can be disposed under the semiconductor layer 142 to minimize a threshold voltage change due to an external light.

A gate insulating layer 144 is disposed on the semiconductor layer 142 over the entire substrate 140, and a gate electrode 146 is disposed on the gate insulating layer 144 corresponding to the active region 142a.

The gate line GL (of FIG. 1) connected to a gate electrode of the switching TFT can be disposed on the gate insulating layer 144.

An interlayer insulating layer 148 is further disposed on the gate electrode 146 over the entire substrate 140, and a drain electrode 150a and a source electrode 150b are disposed on the interlayer insulating layer 148 corresponding to the drain region 142b and the source region 142c, respectively.

The data line DL (of FIG. 1) can be disposed on the interlayer insulating layer 148. The data line DL can cross the gate line GL to define each subpixel SP and can be connected to a source electrode of the switching TFT.

The interlayer insulating layer 148 and the gate insulating layer 144 can have first and second contact holes exposing the drain region 142b and the source region 142c, respectively, and the drain electrode 150a and the source electrode 150b can be connected to the drain region 142b and the source region 142c through the first and second contact holes, respectively.

The semiconductor layer 142, the gate electrode 146, the drain electrode 150a and the source electrode 150b constitute the driving TFT Td.

Although the driving TFT Td has a top gate type and includes polycrystalline silicon in the first embodiment, the driving TFT Td can have a bottom gate type or can include amorphous silicon or oxide semiconductor material in another embodiment.

A protecting layer 152 is disposed on the driving TFT Td over the entire substrate 140, and a phase retardation pattern 154 is disposed in the emission area EA on the protecting layer 152.

The protecting layer 152 can include an inorganic insulating material such as silicon oxide (SiO2) and silicon nitride (SiNx) or an organic insulating material such as benzocyclobutene (BCB) and acrylic resin.

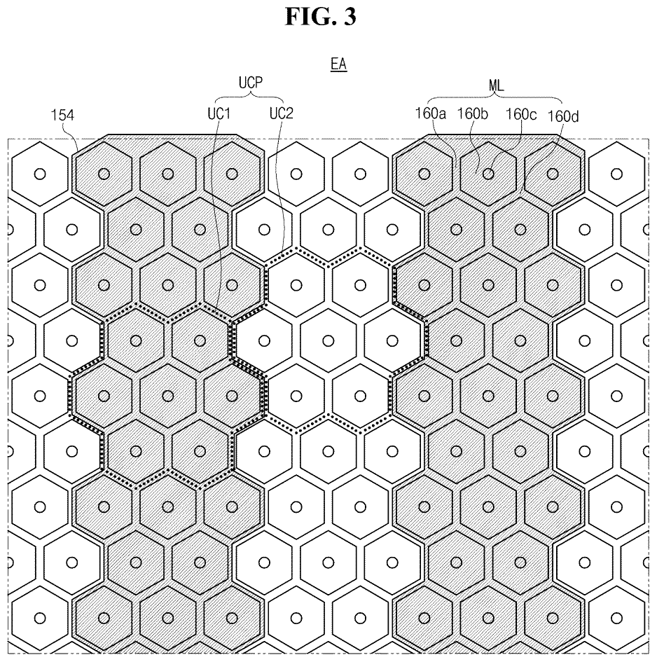

The phase retardation pattern 154 is disposed to correspond to one of first and second unit cells UC1 and UC2 (of FIG. 3) of a microlens array and delays a phase of a light incident to one of the first and second unit cells UC1 and UC2 or a light emitted from one of the first and second unit cells UC1 and UC2. For example, the phase retardation pattern 154 can include an inorganic insulating material such as silicon nitride (SiNx).

The detailed disposition and the phase retardation of the phase retardation pattern 154 can be illustrated later.

A planarizing layer 156 is disposed on the phase retardation pattern 154 over the entire substrate 140, and a passivation layer 158 is disposed on the planarizing layer 156 over the entire substrate 140.

The planarizing layer 156 has a flat top surface by planarizing a step difference of the phase retardation pattern 154. For example, the planarizing layer can include an organic insulating material such as benzocyclobutene (BCB) and acrylic resin.

The passivation layer 158 covers and protects the planarizing layer 156. For example, the passivation layer 158 can include an inorganic insulating material such as silicon oxide (SiO2).

A wavelength converting layer can be disposed on the passivation layer 158. The wavelength converting layer can include a color filter that transmits a component of a predetermined wavelength among a white colored light emitted from the LED De toward the substrate 140, a quantum dot (QD) that emits a light of a predetermined wavelength through a re-emission using a white colored light emitted from the LED De toward the substrate 140 or a color filter having a quantum dot.

An overcoat layer 160 is disposed on the passivation layer 158 over the entire substrate 140. The overcoat layer 160, the passivation layer 158, the planarizing layer 156 and the protecting layer 152 have a third contact hole exposing the source electrode 150b.

A top surface of the overcoat layer 160 includes a first maximum portion 160a having a relatively great height, a minimum portion 160c having a relatively small height and a slanting portion 160b between the first maximum portion 160a and the minimum portion 160c. The minimum portion 160c at a center thereof, the slanting portion 160b at both sides of the minimum portion 160c and the first maximum portion 160a at both sides of the slanting portion 160b constitute a single microlens ML.

In the first embodiment, the first maximum portion 160a, the slanting portion 160b and the minimum portion 160c exemplarily have a downwardly convex shape. In another embodiment, the first maximum portion 160a and an upper half part of the slanting portion 160b can have an upwardly convex shape and a lower half part of the slanting portion 160b and the minimum portion 160c can have a downwardly convex shape. Alternatively, in another embodiment, the first maximum portion 160a, the slanting portion 160b and the minimum portion 160c can have an upwardly convex shape. The shape of the microlens ML can be variously modified.

For example, the overcoat layer 160 can include one of acrylic resin, epoxy resin, phenolic resin, polyamide resin, polyimide resin, unsaturated polyester resin, polyphenylene resin, polyphenylene sulfide resin, benzocyclobutene and photoresist.

A first electrode 162 is disposed in the emission area EA on the overcoat layer 160. The first electrode 162 can be connected to the source electrode 150b through the third contact hole in the overcoat layer 160, the passivation layer 158, the planarizing layer 156 and the protecting layer 152.

For example, the first electrode 162 can be an anode including a material having a relatively high work function.

A bank layer 164 is disposed in the non-emission area NEA on the first electrode 162. The bank layer 164 covers an edge portion of the first electrode 162 and has an opening exposing a central portion of the first electrode 162.

The first maximum portion 160a, the slanting portion 160b and the minimum portion 160c constituting the microlens ML are disposed in the entire opening of the bank layer 164. For example, the first maximum portion 160a, the slanting portion 160b and the minimum portion 160c of the outermost microlens ML can be disposed to contact an edge portion of the bank layer 164.

The opening of the bank layer 164 can be disposed to correspond to the wavelength converting layer. For example, the edge portion of the bank layer 164 can overlap an edge portion of the wavelength converting layer to minimize a leakage of a light not passing through the wavelength converting layer.

An emitting layer 166 is disposed on the first electrode 162 over the entire substrate 140. The emitting layer 166 can have a single layer of an emitting material or a multiple layer of a hole injecting layer, a hole transporting layer, an emitting material layer, an electron transporting layer and an electron injecting layer.

A second electrode 168 is disposed on the emitting layer 166 over the entire substrate 140. For example, the second electrode 168 can be a cathode including a material having a relatively low work function.

The first electrode 162, the emitting layer 166 and the second electrode 168 constitute the LED De.

The first electrode 162, the emitting layer 166 and the second electrode 168 over the overcoat layer 160 are formed along a shape of the first maximum portion 160a, the slanting portion 160b and the minimum portion 160c of the top surface of the overcoat layer 160 to have a shape of the microlens ML.

A face seal 170 is disposed on the LED De, and a protecting film 172 is disposed on the face seal 170. The face seal 170 can include an organic insulating material or an inorganic insulating material that is transparent and has an adhesion property. The protecting film 172 can have a shape of a thin film.

To prevent penetration of an oxygen or a moisture of an exterior into an interior, the protecting film 172 includes at least two inorganic protecting films. An organic protecting film can be disposed between the at least two inorganic protecting films to improve an impact resistance of the at least two inorganic protecting films.

In a structure where the organic protecting film and the inorganic protecting film are alternately laminated, for preventing penetration of an oxygen or a moisture through a side surface of the organic protecting film, the inorganic protecting film can be disposed to completely wrap the organic protecting film.

For minimizing reflection of an external light, a retardation plate and a polarizing plate can be disposed under the substrate 140.

In the OLED display device 110 according to the first embodiment of the present disclosure, when a voltage is applied to the first and second electrodes 162 and 168, a hole supplied from the first electrode 162 and an electron supplied from the second electrode 168 are transmitted to the emitting layer 166 to constitute an exciton. Further, when the exciton transitions from an excited state to a ground state, a light is generated.

The light generated in the emitting layer 166 is emitted to an exterior through the transparent first electrode 162, and the OLED display device 110 displays an image.

Since the microlens ML is formed in the overcoat layer 160, the first electrode 162, the emitting layer 166 and the second electrode 168 and a path of a light not extracted to an exterior due to repeated total reflection in the emitting layer 166 is changed toward the substrate 140, a light extraction efficiency is maximized.

Further, since the phase retardation pattern 154 is disposed to correspond to one of the adjacent two unit cells, an interference fringe of the adjacent two unit cells due to reflection of an external light is removed and a quality of reflection visibility is improved.

Although the protecting layer 152, the phase retardation pattern 154, the planarizing layer 156 and the passivation layer 158 are sequentially disposed between the interlayer insulating layer 148 and the overcoat layer 160 in the first embodiment, the protecting layer 152 and the passivation layer 156 can be omitted and the phase retardation pattern 154 and the planarizing layer 156 can be disposed between the interlayer insulating layer 148 and the overcoat layer 160 in another embodiment.

The phase retardation pattern of the OLED display device 110 will be described with reference to the drawings.

FIG. 3 is a plan view showing an example of an emission area of an organic light emitting diode display device according to the first embodiment of the present disclosure.

In FIG. 3, each emission area EA of the OLED display device 110 according to the first embodiment of the present disclosure includes a microlens array having a plurality of microlenses ML, and the plurality of microlenses ML can have a honeycomb shape of a hexagon in a plan view.

In another embodiment, the plurality of microlenses ML can have a honeycomb shape of one of a circle, an ellipse and a tetragon.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes the minimum portion 160c of a circular shape at a center thereof, the slanting portion 160b at both sides of the minimum portion 160c and the first maximum portion 160a of a hexagonal shape at both sides of the slanting portion 160b.

A portion where the adjacent two microlenses ML contact each other constitutes the first maximum portion 160a, and a portion where the adjacent three microlenses ML contact each other constitutes a second maximum portion 160d. A height of the second maximum portion 160d can be greater than a height of the first maximum portion 160a.

Although the minimum portion 160c has a circular shape in FIG. 3, a shape of the minimum portion 160c is not limited thereto.

The first electrode 162, the emitting layer 166 and the second electrode 168 over the overcoat layer 160 are formed to have the same shape as the first maximum portion 160a, the slanting portion 160b, the minimum portion 160c and the second maximum portion 160d of the microlens ML of the overcoat layer 160.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

The phase retardation pattern 154 under the overcoat layer 160 can be disposed to correspond to one of the adjacent two unit cells. The adjacent two unit cells can mean two unit cells whose border lines contact each other.

For example, among the adjacent first and second unit cells UC1 and UC2, the phase retardation pattern 154 can be disposed only under the first unit cell UC1 and may not be disposed under the second unit cell UC2. As a result, the phase retardation pattern 154 can overlap the first unit cell UC1 and may not overlap (can be separated from) the second unit cell UC2.

In the OLED display device 110 according to the first embodiment of the present disclosure, the phase retardation pattern 154 can have a shape of a plurality of rectangles which are disposed along the vertical direction and whose both sides facing along the horizontal direction have an uneven portion. A width between concave portions of both sides of each rectangular shape can correspond to a width of the two microlenses ML, and a width between convex portions of both sides of each rectangular shape can correspond to a width of the three microlenses ML.

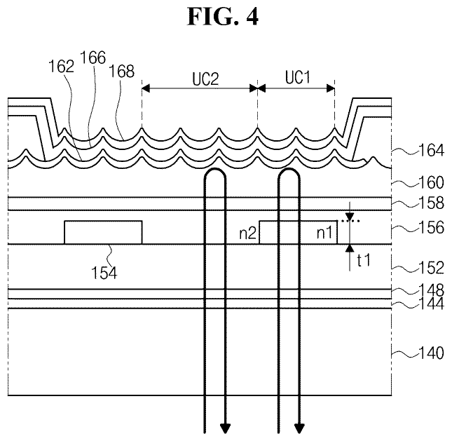

FIG. 4 is a cross-sectional view showing an example of a path of an external light in an organic light emitting diode display device according to the first embodiment of the present disclosure.

In FIG. 4, a light incident to an outer surface of the substrate 140 is reflected by the microlens ML of the overcoating layer 160 to be emitted through the substrate 140, and the lights reflected by the seven microlenses ML of a single unit cell can generate an interference fringe such as a rainbow stain.

In the OLED display device 110 according to the first embodiment of the present disclosure, since the phase retardation pattern 154 is disposed to correspond to one of the adjacent two unit cells, a destructive interference occurs between the lights reflected by the adjacent two unit cells. As a result, an interference fringe generated by the adjacent two unit cells is removed.

Among first and second unit cells UC1 and UC2 adjacent to each other, the phase retardation pattern 154 is disposed under the first unit cell UC1 and is not disposed under the second unit cell UC2.

A first external light EL1 incident to the first unit cell UC1 from an exterior under the substrate 140 passes through the substrate 140, the gate insulating layer 144, the interlayer insulating layer 148, the protecting layer 152, the phase retardation pattern 154, the planarizing layer 156, the passivation layer 158 and the overcoat layer 160 to be reflected by the first unit cell UC1 of the microlens array. Then, the reflected first external light EL1 passes through the overcoat layer 160, the passivation layer 158, the planarizing layer 156, the phase retardation pattern 154, the protecting layer 152, the interlayer insulating layer 148, the gate insulating layer 144 and the substrate 140 again to be emitted to the exterior.

A second external light EL2 incident to the second unit cell UC2 from an exterior under the substrate 140 passes through the substrate 140, the gate insulating layer 144, the interlayer insulating layer 148, the protecting layer 152, the planarizing layer 156, the passivation layer 158 and the overcoat layer 160 to be reflected by the second unit cell UC2 of the microlens array. Then, the reflected second external light EL2 passes through the overcoat layer 160, the passivation layer 158, the planarizing layer 156, the protecting layer 152, the interlayer insulating layer 148, the gate insulating layer 144 and the substrate 140 again to be emitted to the exterior.

The first and second external lights EL1 and EL2 can be reflected by the first and second unit cells UC1 and UC2, respectively, to generate an interference fringe. The first external light EL1 passes through the phase retardation pattern 154 having a first refractive index n1 and a first thickness t1, while the second external light EL2 does not pass through the phase retardation pattern 154 and passes through only the planarizing layer 156 having a second refractive index n2.

As a result, the first and second external lights EL1 and EL2 have a path difference of:

$$2 * Δ n * t 1 ( = 2 * ( n 1 - n 2 ) * t 1 ) ,$$

and the path difference is interpreted as a phase difference of:

$$( 2 π / λ ) * 2 * Δ n * t 1 ( = ( 2 π / λ ) * 2 * ( n 1 - n 2 ) * t 1 = 4 π * ( n 1 - n 2 ) * t 1 / λ ) .$$

Here, Δn is a refractive index difference between the planarizing layer 156 and the phase retardation pattern 154, and λ is a wavelength of the first and second external lights EL1 and EL2.

When the path difference becomes an odd number multiple of a half wavelength (λ2) or the phase difference becomes an odd number multiple of a half phase (π), the reflected first and second external lights EL1 and EL2 can be destructively interfered with each other to be removed.

When the first refractive index n1 and the first thickness t1 of the phase retardation pattern 154 and the second refractive index n2 of the planarizing layer 156 are determined to satisfy the following equation (1) (a case that the odd number multiple is 1 time), the interference fringe of the reflected first and second external lights EL1 and EL2 can be removed.

$$4 π * ( n 1 - n 2 ) * t 1 / λ = π \qquad [ Equation 1 ]$$

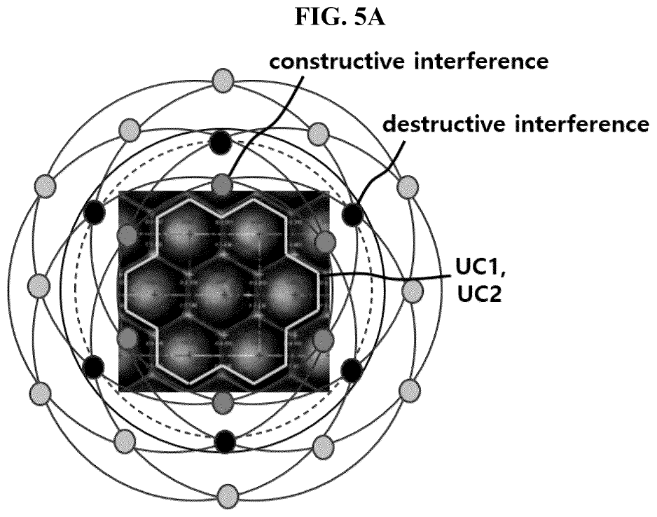

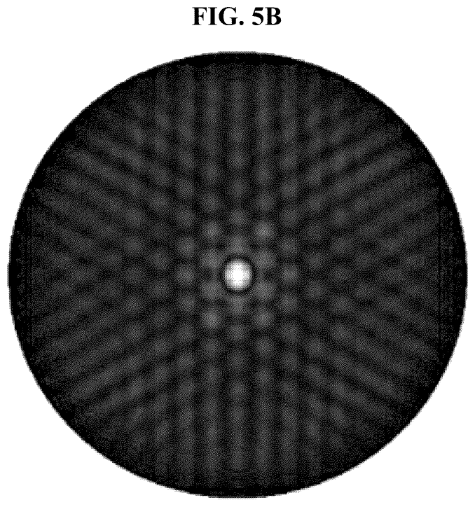

FIG. 5A is a view showing an example of a constructive interference and a destructive interference of a unit cell of an organic light emitting diode display device according to the first embodiment of the present disclosure, and FIG. 5B is a view showing an example of an interference fringe of a unit cell of an organic light emitting diode display device according to the first embodiment of the present disclosure.

In FIG. 5A, the seven microlenses ML including the single microlens ML at a center thereof and the six microlenses ML surrounding the single microlens ML are defined as one unit cell UC1 and UC2 in the microlens array of the OLED display device 110 according to the first embodiment of the present disclosure, and the reflected lights by the seven microlenses ML of the single unit cell UC1 and UC2 form a constructive interference and a destructive interference according to a region.

In FIG. 5B, the reflected lights by the seven microlenses ML of the single unit cell UC1 and UC2 form a constructive interference and a destructive interference to generate an interference fringe such as a rainbow stain.

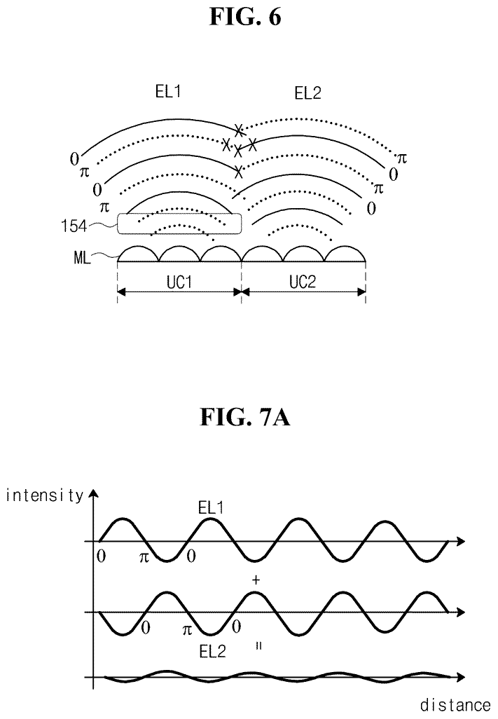

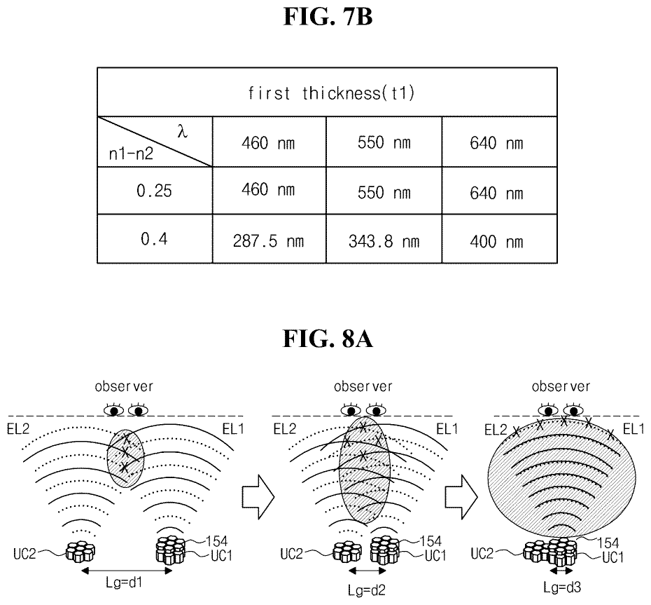

FIG. 6 is a view showing an example of an interference of lights reflected by first and second unit cells of an organic light emitting diode display device according to the first embodiment of the present disclosure, FIG. 7A is a view showing an example of a destructive interference of first and second external lights of an organic light emitting diode display device according to the first embodiment of the present disclosure, and FIG. 7B is a view showing an example of a first thickness of a phase retardation pattern for a destructive interference of first and second external lights of an organic light emitting diode display device according to the first embodiment of the present disclosure.

In FIG. 6, wave fronts of phases of π, 0, π and 0 of the first external light EL1 reflected by the first unit cell UC1 of the microlens array and having passed through the phase retardation pattern 154 twice destructively interfere with wave fronts of phases of 0, π, 0 and π of the second external light EL2 reflected by the second unit cell UC2 of the microlens array and not having passed through the phase retardation pattern 154, respectively, in the OLED display device 110 according to the first embodiment of the present disclosure. As a result, the reflected first and second external lights EL1 and EL2 are removed.

In FIG. 7A, the wave fronts of phases of π, 0, π and 0 of the first external light EL1 and the wave fronts of phases of 0, π, 0 and π of the second external light EL2 are destructively interfere with each other to be removed in the OLED display device 110 according to the first embodiment of the present disclosure.

In FIG. 7B, the first thickness t1 of the phase retardation pattern 154 for a destructive interference can be determined according to a difference (Δ n=n1-n2) between the first refractive index n1 of the phase retardation pattern 154 and the second refractive index n2 of the planarizing layer 156 and the wavelength λ of the first and second external lights EL1 and EL2.

The above equation (1) for a destructive interference can be changed to the following equation (2), and the first thickness t1 can be proportional to the wavelength λ and can be inversely proportional to the refractive index difference (n1-n2).

$$t 1 = λ / ( 4 * ( n 1 - n 2 ) ) \qquad [ Equation 2 ]$$

For example, when the first refractive index n1 of the phase retardation pattern 154 is about 1.9 and the second refractive index n2 of the planarizing layer 156 is about 1.65, the refractive index difference (n1-n2) is about 0.25, and the first thickness t1 for a destructive interference can be determined as about 460 nm, about 550 nm and about 640 nm with respect to external lights (red, green, blue) of wavelengths of about 460 nm, about 550 nm and about 640 nm, respectively.

When the first refractive index n1 of the phase retardation pattern 154 is about 1.9 and the second refractive index n2 of the planarizing layer 156 is about 1.5, the refractive index difference (n1-n2) is about 0.4, and the first thickness t1 for a destructive interference can be determined as about 287.5 nm, about 343.8 nm and about 400 nm with respect to external lights (red, green, blue) of wavelengths of about 460 nm, about 550 nm and about 640 nm, respectively.

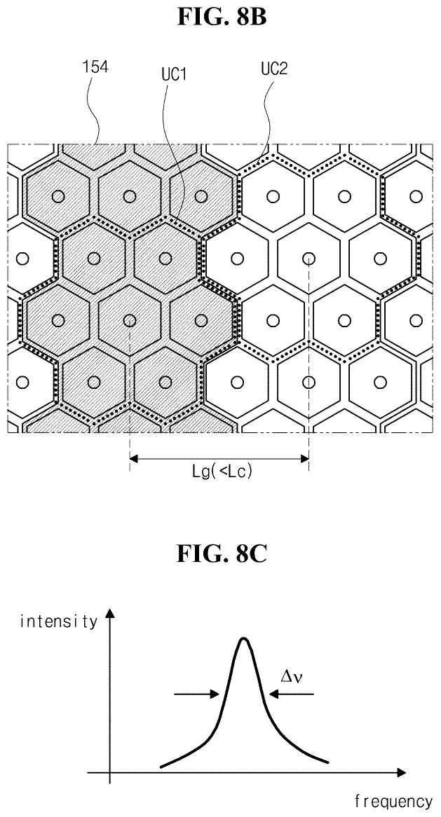

FIG. 8A is a view showing an example of a removal degree of an interference fringe with respect to a gap length between first and second unit cells of an organic light emitting diode display device according to the first embodiment of the present disclosure, FIG. 8B is a plan view showing an example of a gap length between adjacent first and second unit cells of an organic light emitting diode display device according to the first embodiment of the present disclosure, and FIG. 8C is a view showing an example of a coherence length of an organic light emitting diode display device according to the first embodiment of the present disclosure.

In FIG. 8A, when a gap length Lg between centers of the first and second unit cells UC1 and UC2 is a first distance d1 of a relatively great value, the wave fronts of the first and second external lights EL1 and EL2 reflected by the first and second unit cells UC1 and UC2 do not overlap (are separated from) each other, and a destructive interference does not occur. As a result, an interference fringe of the first and second unit cells UC1 and UC2 is not removed.

When the gap length Lg between the centers of the first and second unit cells UC1 and UC2 is a second distance d2 smaller than the first distance d1, the wave fronts of the first and second external lights EL1 and EL2 reflected by the first and second unit cells UC1 and UC2 partially overlap each other in a partial viewing angle range, and a destructive interference partially occurs. As a result, an interference fringe of the first and second unit cells UC1 and UC2 is partially removed.

When the gap length Lg between the centers of the first and second unit cells UC1 and UC2 is a third distance d3 smaller than the second distance d2, the wave fronts of the first and second external lights EL1 and EL2 reflected by the first and second unit cells UC1 and UC2 overlap each other in the entire viewing angle range, and a destructive interference entirely occurs. As a result, an interference fringe of the first and second unit cells UC1 and UC2 is entirely removed.

In FIG. 8B, when the gap length Lg between the centers of the first and second unit cells UC1 and UC2 of the microlens array is smaller than a coherence length Lc, the wave fronts of the first and second external lights EL1 and EL2 overlap each other in the entire viewing angle range, and a destructive interference occurs. As a result, an interference fringe of the first and second unit cells UC1 and UC2 of the microlens array is entirely removed.

In FIG. 8C, a light emitted from a light source has a peak of an intensity at a specific frequency band. As a width of a frequency band corresponding to a peak of an emission spectrum of the light source is reduced, a coherence length Lc that is a length where a phase and a wave front of a light are kept constant increases.

For example, a sunlight having passed through the air can have a coherence time of about 1 fsec and a coherence length Lc of about 100 nm, a light of a light emitting diode (LED) can have a coherence time of about 10 fsec and a coherence length Lc of about 10 m, and a light of a mercury fluorescent lamp can have a coherence time of about 0.25 nsec longer than the coherence time of the LED and a coherence length Lc of about 1 mm to about 9 mm longer than the coherence length of the LED.

Since the coherence length Lc of the sunlight is equal to or smaller than 1/10 of a size (a width, a horizontal length, a vertical length) of the single microlens MIL, the sunlight reflected by each of the first and second unit cells UC1 and UC2 does not generate an interference fringe, and deterioration such as a rainbow stain does not occur.

The coherence length Lc of about 10 m of the LED is similar to the size (the width, the horizontal length, the vertical length) of about 12 m of each of the first and second unit cells UC1 and UC2, and the coherence length Lc of several mm of the fluorescent lamp is greater than the size (the width, the horizontal length, the vertical length) of about 12 m of each of the first and second unit cells UC1 and UC2. As a result, each of the light of the LED and the light of the fluorescent lamp reflected by the first and second unit cells UC1 and UC2 generates an interference fringe, and deterioration such as a rainbow stain occurs.

In the OLED display device 110 according to the first embodiment of the present disclosure, an interference fringe of the first and second unit cells UC1 and UC2 is removed due to the phase retardation pattern 154, and a quality of reflection visibility is improved.

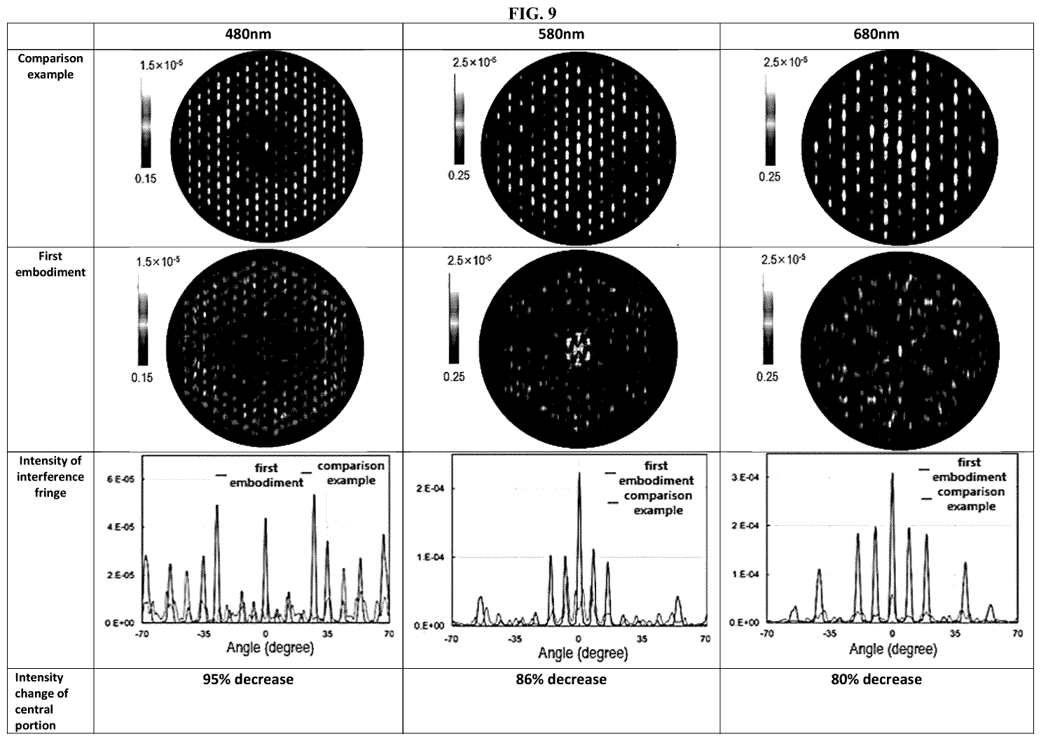

FIG. 9 is a view showing an example of an interference fringe with respect to a wavelength of an organic light emitting diode display device according to the first embodiment of the present disclosure.

In FIG. 9, an external light of wavelengths of about 480 nm, about 580 nm and about 680 nm incident to an OLED display device according to a comparison example that does not include a phase retardation pattern is reflected by the first and second unit cells UC1 and UC2 of the microlens array to generate an interference fringe such as a rainbow stain. Although an external light of wavelengths of about 480 nm, about 580 nm and about 680 nm incident to the OLED display device 110 according to the first embodiment of the present disclosure is reflected by the first and second unit cells UC1 and UC2 of the microlens array, an interference fringe such as a rainbow stain is removed due to the phase retardation pattern 154.

As a result, an intensity of an interference fringe of the external light of wavelengths of about 480 nm, about 580 nm and about 680 nm according to the first embodiment is reduced in a viewing angle range less than about 70 degrees as compared with an intensity of an interference fringe of the external light of wavelengths of about 480 nm, about 580 nm and about 680 nm according to a comparison example. For example, the intensities of central portions of the interference fringes of the first embodiment are reduced by about 95%, about 86% and about 80% as compared with the intensities of central portions of the interference fringes of a comparison example.

In the OLED display device 110 according to the first embodiment of the present disclosure, the phase retardation pattern 154 is disposed along the vertical direction to correspond to one of the adjacent first and second unit cells UC1 and UC2 of the microlens array of the overcoat layer 160 and has a rectangular shape whose both sides facing along the horizontal direction have an uneven portion. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 154 and the second refractive index of the planarizing layer 156. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 154 of the rectangular shape is disposed along the vertical direction, the interference fringe of the first and second unit cells UC1 and UC2 along the left-right direction is further removed due to the destructive interference, and the quality of reflection visibility is improved.

In another embodiment, the phase retardation pattern can be modified to have various shapes.

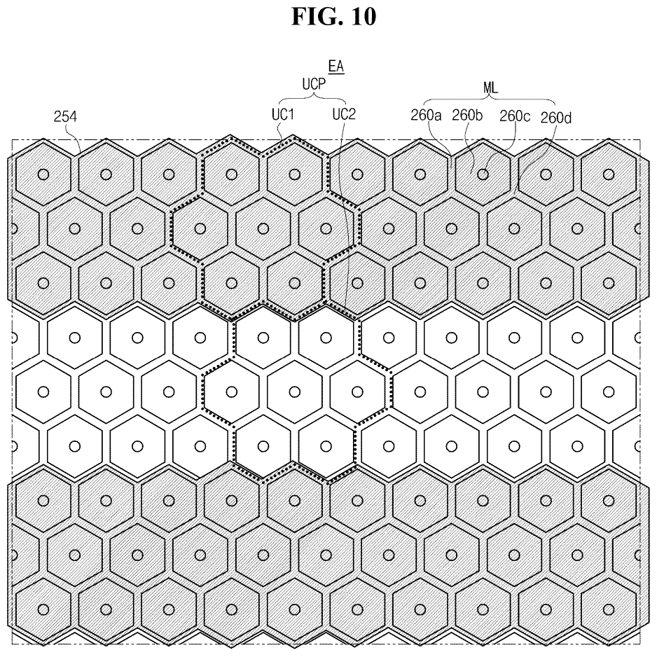

FIG. 10 is a plan view showing an example of an emission area of an organic light emitting diode display device according to a second embodiment of the present disclosure. Illustration on one or more parts that are the same as those of the first embodiment can be omitted.

In FIG. 10, an emission area EA of an organic light emitting diode (OLED) display device according to the second embodiment of the present disclosure includes a microlens array having a plurality of microlenses ML, and the plurality of microlenses ML can have a honeycomb shape of a hexagon in a plan view.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes a minimum portion 260c of a circular shape at a center thereof, a slanting portion 260b at both sides of the minimum portion 260c and a first maximum portion 260a of a hexagonal shape at both sides of the slanting portion 260b.

A portion where the adjacent two microlenses ML contact each other constitutes the first maximum portion 260a, and a portion where the adjacent three microlenses ML contact each other constitutes a second maximum portion 260d. A height of the second maximum portion 260d can be greater than a height of the first maximum portion 260a.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

A phase retardation pattern 254 under an overcoat layer can be disposed to correspond to one of the adjacent two unit cells.

For example, among the adjacent first and second unit cells UC1 and UC2, the phase retardation pattern 254 can be disposed only under the first unit cell UC1 and may not be disposed under the second unit cell UC2.

In the OLED display device according to the second embodiment of the present disclosure, the phase retardation pattern 254 can have a shape of a plurality of rectangles which are disposed along a horizontal direction and whose both sides facing along a vertical direction have an uneven portion. A width between concave portions of both sides of each rectangular shape can correspond to a width of the two microlenses ML, and a width between convex portions of both sides of each rectangular shape can correspond to a width of the two and half (2.5) microlenses ML.

In the OLED display device according to the second embodiment of the present disclosure, the phase retardation pattern 254 is disposed along the horizontal direction to correspond to one of the adjacent first and second unit cells UC1 and UC2 of the microlens array of the overcoat layer and has a rectangular shape whose both sides facing along the vertical direction have an uneven portion. As a result, the interference fringe of the first and second unit cells UC1 and UC2 is removed due to the destructive interference, and a quality of reflection visibility is improved.

Further, the interference fringes of the first and second unit cells UC1 and UC2 are destructively interfered with each other by adjusting a first refractive index and a first thickness of the phase retardation pattern 254 and a second refractive index of the planarizing layer. As a result, the interference fringe of the first and second unit cells UC1 and UC2 are removed in a relatively wide viewing angle range less than about 70 degrees for an external light of an entire wavelength band, and the quality of reflection visibility is improved.

In addition, since the phase retardation pattern 254 of the rectangular shape is disposed along the horizontal direction, the interference fringe of the first and second unit cells UC1 and UC2 along the up-down direction is further removed due to a destructive interference, and the quality of reflection visibility is improved.

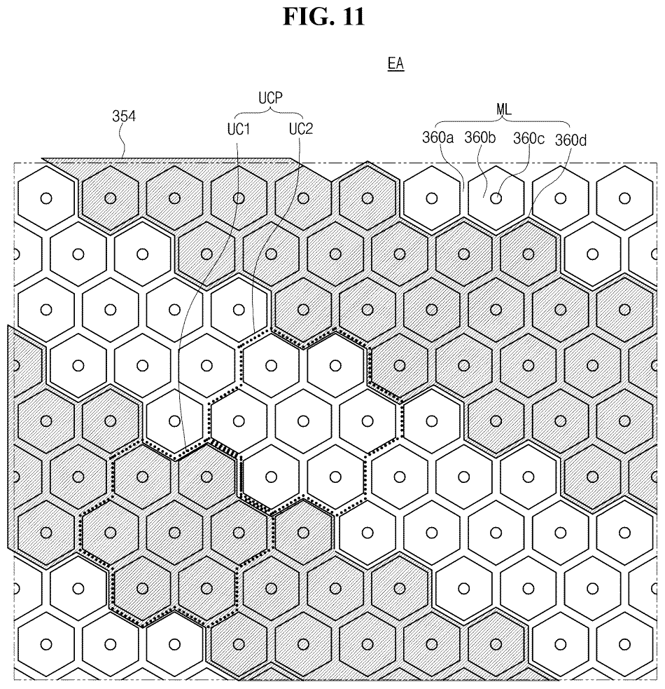

FIG. 11 is a plan view showing an example of an emission area of an organic light emitting diode display device according to a third embodiment of the present disclosure. Illustration on one or more parts that are the same as those of at least one of the first and second embodiments can be omitted.

In FIG. 11, an emission area EA of an organic light emitting diode (OLED) display device according to the third embodiment of the present disclosure includes a microlens array having a plurality of microlenses ML, and the plurality of microlenses ML can have a honeycomb shape of a hexagon in a plan view.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes a minimum portion 360c of a circular shape at a center thereof, a slanting portion 360b at both sides of the minimum portion 360c and a first maximum portion 360a of a hexagonal shape at both sides of the slanting portion 360b.

A portion where the adjacent two microlenses ML contact each other constitutes the first maximum portion 360a, and a portion where the adjacent three microlenses ML contact each other constitutes a second maximum portion 360d. A height of the second maximum portion 360d can be greater than a height of the first maximum portion 360a.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

A phase retardation pattern 354 under an overcoat layer can be disposed to correspond to one of the adjacent two unit cells.

For example, among the adjacent first and second unit cells UC1 and UC2, the phase retardation pattern 354 can be disposed only under the first unit cell UC1 and may not be disposed under the second unit cell UC2.

In the OLED display device according to the third embodiment of the present disclosure, the phase retardation pattern 354 can have a shape of a plurality of rectangles which are disposed along a first diagonal direction and whose both sides facing along a second diagonal direction crossing the first diagonal direction have an uneven portion. A width between concave portions of both sides of each rectangular shape can correspond to a width of the two microlenses ML, and a width between convex portions of both sides of each rectangular shape can correspond to a width of the three microlenses ML.

In the OLED display device according to the third embodiment of the present disclosure, the phase retardation pattern 354 is disposed along the first diagonal direction to correspond to one of the adjacent first and second unit cells UC1 and UC2 of the microlens array of the overcoat layer and has a rectangular shape whose both sides facing along the second diagonal direction have an uneven portion. As a result, the interference fringe of the first and second unit cells UC1 and UC2 is removed due to the destructive interference, and a quality of reflection visibility is improved.

Further, the interference fringes of the first and second unit cells UC1 and UC2 are destructively interfered with each other by adjusting a first refractive index and a first thickness of the phase retardation pattern 354 and a second refractive index of the planarizing layer. As a result, the interference fringe of the first and second unit cells UC1 and UC2 are removed in a relatively wide viewing angle range less than about 70 degrees for an external light of an entire wavelength band, and the quality of reflection visibility is improved.

In addition, since the phase retardation pattern 354 of the rectangular shape is disposed along the first diagonal direction, the interference fringe of the first and second unit cells UC1 and UC2 along a diagonal direction is further removed due to a destructive interference, and the quality of reflection visibility is improved.

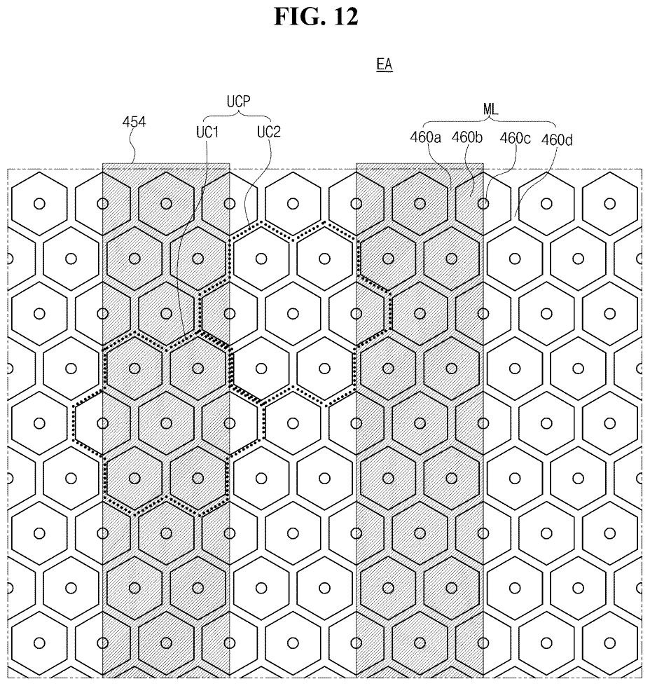

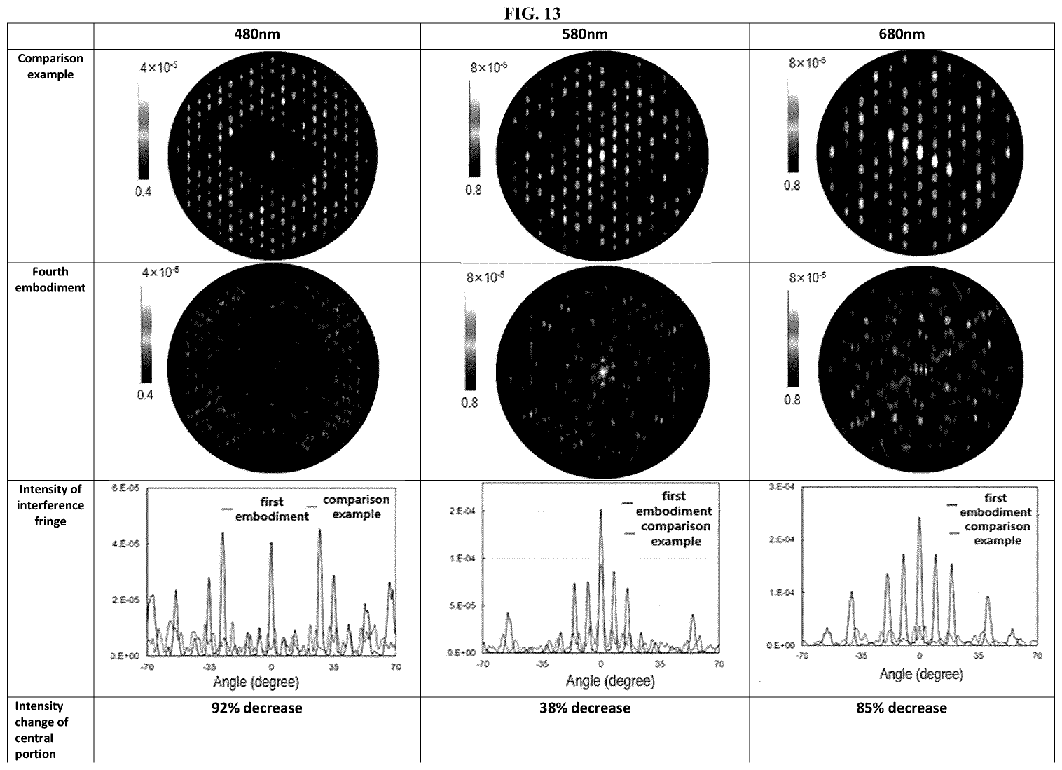

FIG. 12 is a plan view showing an example of an emission area of an organic light emitting diode display device according to a fourth embodiment of the present disclosure, and FIG. 13 is a view showing an example of an interference fringe with respect to a wavelength of an organic light emitting diode display device according to the fourth embodiment of the present disclosure. Illustration on one or more parts that are the same as those of at least one of the first to third embodiments can be omitted.

In FIG. 12, an emission area EA of an organic light emitting diode (OLED) display device according to the fourth embodiment of the present disclosure includes a microlens array having a plurality of microlenses ML, and the plurality of microlenses ML can have a honeycomb shape of a hexagon in a plan view.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes a minimum portion 460c of a circular shape at a center thereof, a slanting portion 460b at both sides of the minimum portion 460c and a first maximum portion 460a of a hexagonal shape at both sides of the slanting portion 460b.

A portion where the adjacent two microlenses ML contact each other constitutes the first maximum portion 460a, and a portion where the adjacent three microlenses ML contact each other constitutes a second maximum portion 460d. A height of the second maximum portion 460d can be greater than a height of the first maximum portion 460a.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

A phase retardation pattern 454 under an overcoat layer can be disposed to correspond to one of the adjacent two unit cells.

For example, among the adjacent first and second unit cells UC1 and UC2, the phase retardation pattern 454 can be disposed only under the first unit cell UC1 and may not be disposed under the second unit cell UC2.

In the OLED display device according to the fourth embodiment of the present disclosure, the phase retardation pattern 454 can have a shape of a plurality of rectangles which are disposed along the vertical direction. A width between both sides of each rectangular shape can correspond to a width of the two microlenses ML.

In FIG. 13, an external light of wavelengths of about 480 nm, about 580 nm and about 680 nm incident to an OLED display device according to a comparison example that does not include a phase retardation pattern is reflected by the first and second unit cells UC1 and UC2 of the microlens array to generate an interference fringe such as a rainbow stain. Although an external light of wavelengths of about 480 nm, about 580 nm and about 680 nm incident to the OLED display device according to the fourth embodiment of the present disclosure is reflected by the first and second unit cells UC1 and UC2 of the microlens array, an interference fringe such as a rainbow stain is removed due to the phase retardation pattern 454.

As a result, an intensity of an interference fringe of the external light of wavelengths of about 480 nm, about 580 nm and about 680 nm according to the fourth embodiment is reduced in a viewing angle range less than about 70 degrees as compared with an intensity of an interference fringe of the external light of wavelengths of about 480 nm, about 580 nm and about 680 nm according to a comparison example. For example, the intensities of central portions of the interference fringes of the fourth embodiment are reduced by about 92%, about 38% and about 85% as compared with the intensities of central portions of the interference fringes of a comparison example.

In the OLED display device according to the fourth embodiment of the present disclosure, the phase retardation pattern 454 is disposed along the vertical direction to correspond to one of the adjacent first and second unit cells UC1 and UC2 of the microlens array of the overcoat layer and has a rectangular shape. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 454 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 454 of the rectangular shape is disposed along the vertical direction, the interference fringe of the first and second unit cells UC1 and UC2 along the left-right direction is further removed due to the destructive interference, and the quality of reflection visibility is improved.

Further, since the phase retardation pattern 454 is formed to have a simple rectangular shape without an unevenness of both sides, the quality of reflection visibility is improved with a simplified fabrication process.

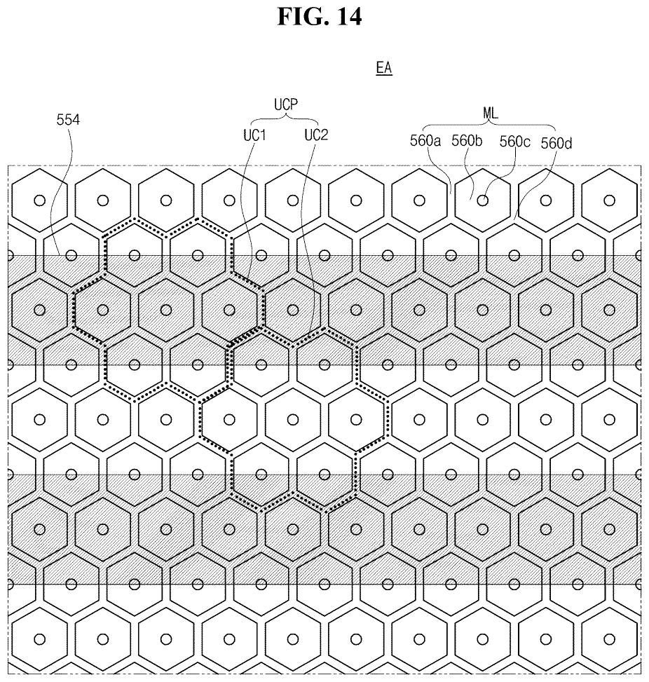

FIG. 14 is a plan view showing an example of an emission area of an organic light emitting diode display device according to a fifth embodiment of the present disclosure. Illustration on one or more parts that are the same as those of at least one of the first to fourth embodiments can be omitted.

In FIG. 14, an emission area EA of an organic light emitting diode (OLED) display device according to the fifth embodiment of the present disclosure includes a microlens array having a plurality of microlenses ML, and the plurality of microlenses ML can have a honeycomb shape of a hexagon in a plan view.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes a minimum portion 560c of a circular shape at a center thereof, a slanting portion 560b at both sides of the minimum portion 560c and a first maximum portion 560a of a hexagonal shape at both sides of the slanting portion 560b.

A portion where the adjacent two microlenses ML contact each other constitutes the first maximum portion 560a, and a portion where the adjacent three microlenses ML contact each other constitutes a second maximum portion 560d. A height of the second maximum portion 560d can be greater than a height of the first maximum portion 560a.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

A phase retardation pattern 554 under an overcoat layer can be disposed to correspond to one of the adjacent two unit cells.

For example, among the adjacent first and second unit cells UC1 and UC2, the phase retardation pattern 554 can be disposed only under the first unit cell UC1 and may not be disposed under the second unit cell UC2.

In the OLED display device according to the fifth embodiment of the present disclosure, the phase retardation pattern 554 can have a shape of a plurality of rectangles which are disposed along the horizontal direction. A width between both sides of each rectangular shape can correspond to a width of the two microlenses ML.

In the OLED display device according to the fifth embodiment of the present disclosure, the phase retardation pattern 554 is disposed along the horizontal direction to correspond to one of the adjacent first and second unit cells UC1 and UC2 of the microlens array of the overcoat layer and has a rectangular shape. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 554 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 554 of the rectangular shape is disposed along the horizontal direction, the interference fringe of the first and second unit cells UC1 and UC2 along the up-down direction is further removed due to the destructive interference, and the quality of reflection visibility is improved.

Further, since the phase retardation pattern 554 is formed to have a simple rectangular shape without an unevenness of both sides, the quality of reflection visibility is improved with a simplified fabrication process.

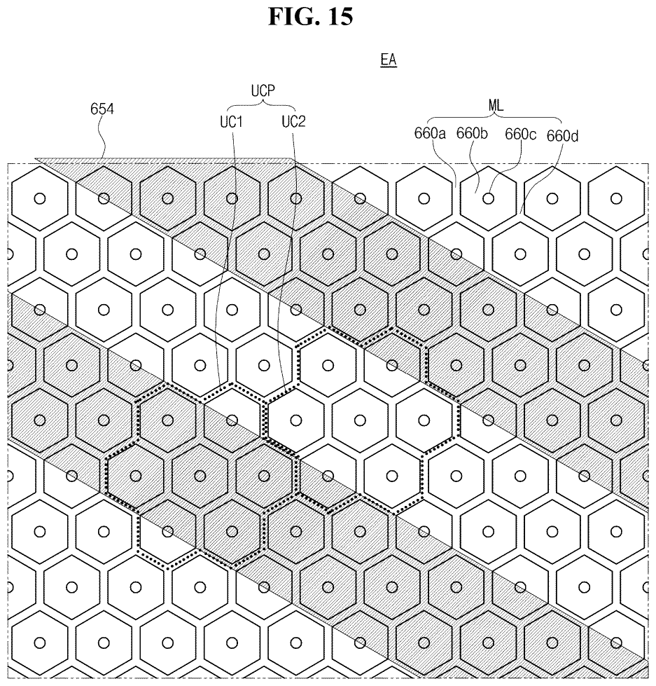

FIG. 15 is a plan view showing an example of an emission area of an organic light emitting diode display device according to a sixth embodiment of the present disclosure. Illustration on one or more parts that are the same as those of at least one of the first to fifth embodiments can be omitted.

In FIG. 15, an emission area EA of an organic light emitting diode (OLED) display device according to the sixth embodiment of the present disclosure includes a microlens array having a plurality of microlenses ML, and the plurality of microlenses ML can have a honeycomb shape of a hexagon in a plan view.

For example, the plurality of microlenses ML each having a hexagonal shape can be arranged in a single line along a horizontal direction (a first direction) and can be alternately arranged along a vertical direction (a second direction) and a diagonal direction (a third direction).

The single microlens ML includes a minimum portion 660c of a circular shape at a center thereof, a slanting portion 660b at both sides of the minimum portion 660c and a first maximum portion 660a of a hexagonal shape at both sides of the slanting portion 660b.

A portion where the adjacent two microlenses ML contact each other constitutes the first maximum portion 660a, and a portion where the adjacent three microlenses ML contact each other constitutes a second maximum portion 660d. A height of the second maximum portion 660d can be greater than a height of the first maximum portion 660a.

A single microlens ML and six microlenses ML surrounding the single microlens ML in the microlens array can be defined as a unit cell that causes an interference fringe such as a rainbow stain (a rainbow mura) having a hexagonal shape due to a structure symmetry.

A phase retardation pattern 654 under an overcoat layer can be disposed to correspond to one of the adjacent two unit cells.

For example, among the adjacent first and second unit cells UC1 and UC2, the phase retardation pattern 654 can be disposed only under the first unit cell UC1 and may not be disposed under the second unit cell UC2.

In the OLED display device according to the sixth embodiment of the present disclosure, the phase retardation pattern 654 can have a shape of a plurality of rectangles which are disposed along a first diagonal direction. A width between both sides of each rectangular shape can correspond to a width of the two microlenses ML.

In the OLED display device according to the sixth embodiment of the present disclosure, the phase retardation pattern 654 is disposed along the first diagonal direction to correspond to one of the adjacent first and second unit cells UC1 and UC2 of the microlens array of the overcoat layer and has a rectangular shape. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 654 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 654 of the rectangular shape is disposed along the first diagonal direction, the interference fringe of the first and second unit cells UC1 and UC2 along a diagonal direction is further removed due to the destructive interference, and the quality of reflection visibility is improved.

Further, since the phase retardation pattern 654 is formed to have a simple rectangular shape without an unevenness of both sides, the quality of reflection visibility is improved with a simplified fabrication process.

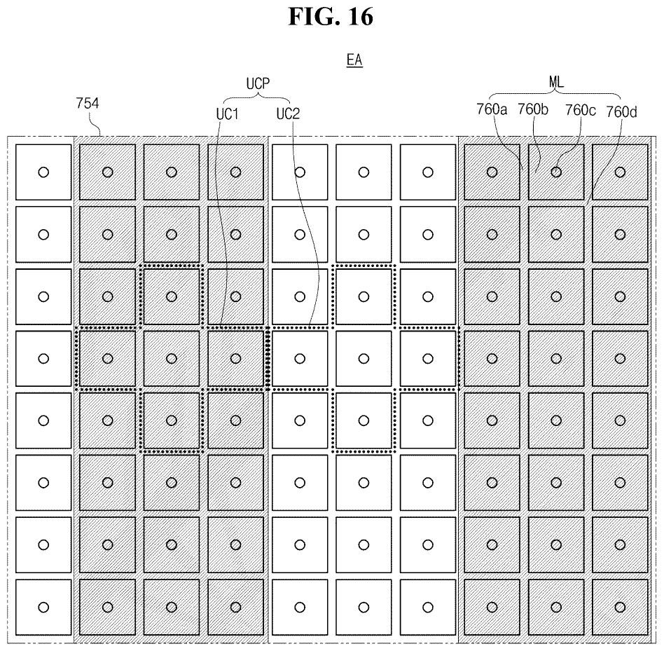

FIG. 16 is a plan view showing an example of an emission area of an organic light emitting diode display device according to a seventh embodiment of the present disclosure. Illustration on one or more parts that are the same as those of at least one of the first to sixth embodiments can be omitted.

In FIG. 16, an emission area EA of an organic light emitting diode (OLED) display device according to the seventh embodiment of the present disclosure includes a microlens array having a plurality of microlenses ML, and the plurality of microlenses ML can have a honeycomb shape of a tetragon in a plan view.

For example, the plurality of microlenses ML each having a tetragonal shape can be arranged in a single line along a horizontal direction (a first direction) and can be alternately arranged along a vertical direction (a second direction) and a diagonal direction (a third direction).

The single microlens ML includes a minimum portion 760c of a circular shape at a center thereof, a slanting portion 760b at both sides of the minimum portion 760c and a first maximum portion 760a of a tetragonal shape at both sides of the slanting portion 760b.

A portion where the adjacent two microlenses ML contact each other constitutes the first maximum portion 760a, and a portion where the adjacent four microlenses ML contact each other constitutes a second maximum portion 760d. A height of the second maximum portion 760d can be greater than a height of the first maximum portion 760a.

A single microlens ML and four microlenses ML surrounding the single microlens ML in the microlens array can be defined as a unit cell that causes an interference fringe such as a rainbow stain (a rainbow mura) having a tetragonal shape due to a structure symmetry.

A phase retardation pattern 754 under an overcoat layer can be disposed to correspond to one of the adjacent two unit cells.

For example, among the adjacent first and second unit cells UC1 and UC2, the phase retardation pattern 754 can be disposed only under the first unit cell UC1 and may not be disposed under the second unit cell UC2.

In the OLED display device according to the seventh embodiment of the present disclosure, the phase retardation pattern 754 can have a shape of a plurality of rectangles which are disposed along the vertical direction. A width between both sides of each rectangular shape can correspond to a width of the three microlenses ML.

In the OLED display device according to the seventh embodiment of the present disclosure, the phase retardation pattern 754 is disposed along the vertical direction to correspond to one of the adjacent first and second unit cells UC1 and UC2 of the microlens array of the overcoat layer and has a rectangular shape. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 754 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 754 of the rectangular shape is disposed along the vertical direction, the interference fringe of the first and second unit cells UC1 and UC2 along the left-right direction is further removed due to the destructive interference, and the quality of reflection visibility is improved.

Further, since the phase retardation pattern 754 is formed to have a simple rectangular shape without an unevenness of both sides, the phase retardation pattern 754 is disposed to coincide with the unit cell accurately and the quality of reflection visibility is improved with a simplified fabrication process.

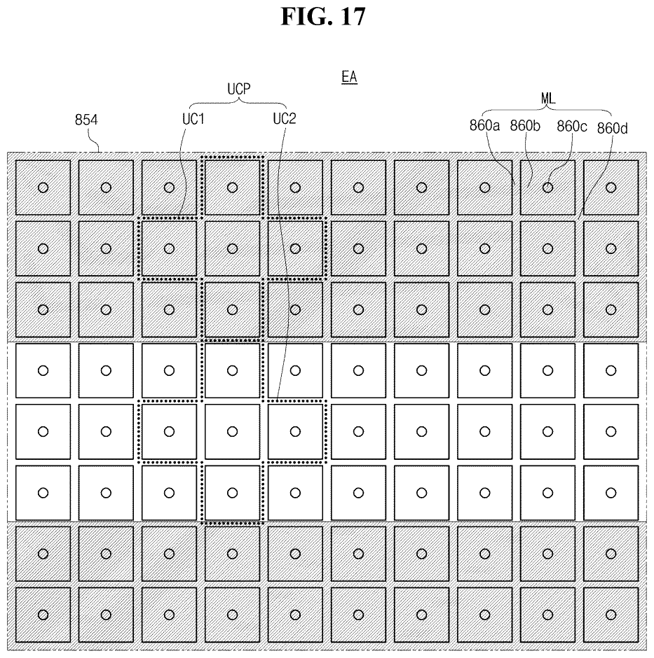

FIG. 17 is a plan view showing an example of an emission area of an organic light emitting diode display device according to an eighth embodiment of the present disclosure. Illustration on one or more parts that are the same as those of at least one of the first to seventh embodiments can be omitted.

In FIG. 17, an emission area EA of an organic light emitting diode (OLED) display device according to the eighth embodiment of the present disclosure includes a microlens array having a plurality of microlenses ML, and the plurality of microlenses ML can have a honeycomb shape of a tetragon in a plan view.

For example, the plurality of microlenses ML each having a tetragonal shape can be arranged in a single line along a horizontal direction (a first direction) and can be alternately arranged along a vertical direction (a second direction) and a diagonal direction (a third direction).

The single microlens ML includes a minimum portion 860c of a circular shape at a center thereof, a slanting portion 860b at both sides of the minimum portion 860c and a first maximum portion 860a of a tetragonal shape at both sides of the slanting portion 860b.

A portion where the adjacent two microlenses ML contact each other constitutes the first maximum portion 860a, and a portion where the adjacent four microlenses ML contact each other constitutes a second maximum portion 860d. A height of the second maximum portion 860d can be greater than a height of the first maximum portion 860a.

A single microlens ML and four microlenses ML surrounding the single microlens ML in the microlens array can be defined as a unit cell that causes an interference fringe such as a rainbow stain (a rainbow mura) having a tetragonal shape due to a structure symmetry.

A phase retardation pattern 854 under an overcoat layer can be disposed to correspond to one of the adjacent two unit cells.

For example, among the adjacent first and second unit cells UC1 and UC2, the phase retardation pattern 854 can be disposed only under the first unit cell UC1 and may not be disposed under the second unit cell UC2.

In the OLED display device according to the eighth embodiment of the present disclosure, the phase retardation pattern 854 can have a shape of a plurality of rectangles which are disposed along the horizontal direction. A width between both sides of each rectangular shape can correspond to a width of the three microlenses ML.

In the OLED display device according to the eighth embodiment of the present disclosure, the phase retardation pattern 854 is disposed along the horizontal direction to correspond to one of the adjacent first and second unit cells UC1 and UC2 of the microlens array of the overcoat layer and has a rectangular shape. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 854 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 854 of the rectangular shape is disposed along the horizontal direction, the interference fringe of the first and second unit cells UC1 and UC2 along the up-down direction is further removed due to the destructive interference, and the quality of reflection visibility is improved.

Further, since the phase retardation pattern 854 is formed to have a simple rectangular shape without an unevenness of both sides, the phase retardation pattern 854 is disposed to coincide with the unit cell accurately and the quality of reflection visibility is improved with a simplified fabrication process.

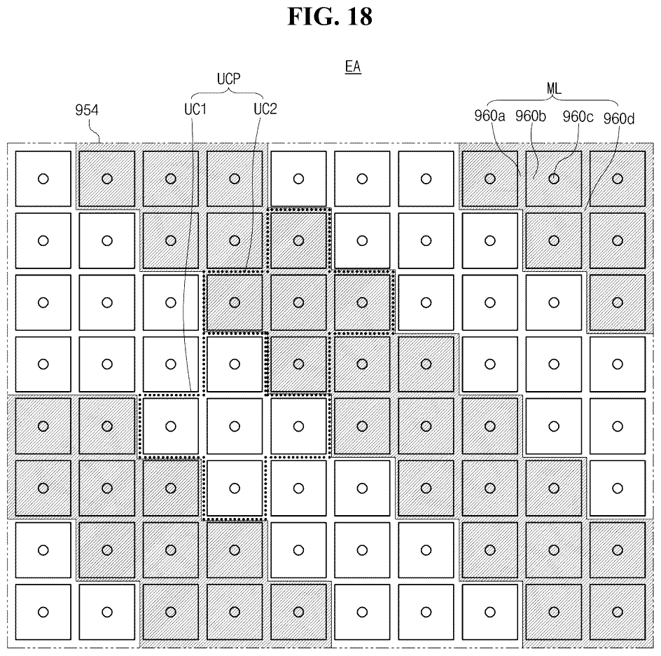

FIG. 18 is a plan view showing an example of an emission area of an organic light emitting diode display device according to a ninth embodiment of the present disclosure. Illustration on one or more parts that are the same as those of at least one of the first to eighth embodiments can be omitted.

In FIG. 18, an emission area EA of an organic light emitting diode (OLED) display device according to the ninth embodiment of the present disclosure includes a microlens array having a plurality of microlenses ML, and the plurality of microlenses ML can have a honeycomb shape of a tetragon in a plan view.

For example, the plurality of microlenses ML each having a tetragonal shape can be arranged in a single line along a horizontal direction (a first direction) and can be alternately arranged along a vertical direction (a second direction) and a diagonal direction (a third direction).

The single microlens ML includes a minimum portion 960c of a circular shape at a center thereof, a slanting portion 960b at both sides of the minimum portion 960c and a first maximum portion 960a of a tetragonal shape at both sides of the slanting portion 960b.

A portion where the adjacent two microlenses ML contact each other constitutes the first maximum portion 960a, and a portion where the adjacent four microlenses ML contact each other constitutes a second maximum portion 960d. A height of the second maximum portion 960d can be greater than a height of the first maximum portion 960a.

A single microlens ML and four microlenses ML surrounding the single microlens ML in the microlens array can be defined as a unit cell that causes an interference fringe such as a rainbow stain (a rainbow mura) having a tetragonal shape due to a structure symmetry.

A phase retardation pattern 954 under an overcoat layer can be disposed to correspond to one of the adjacent two unit cells.

For example, among the adjacent first and second unit cells UC1 and UC2, the phase retardation pattern 954 can be disposed only under the first unit cell UC1 and may not be disposed under the second unit cell UC2.

In the OLED display device according to the ninth embodiment of the present disclosure, the phase retardation pattern 954 can have a shape of a plurality of rectangles which are disposed along a first diagonal direction and whose both sides facing along a second diagonal direction crossing the first diagonal direction have an uneven portion. A width between concave portions of both sides of each rectangular shape can correspond to a width of the one microlens ML, and a width between convex portions of both sides of each rectangular shape can correspond to a width of the two microlenses ML.

In the OLED display device according to the ninth embodiment of the present disclosure, the phase retardation pattern 954 is disposed along the first diagonal direction to correspond to one of the adjacent first and second unit cells UC1 and UC2 of the microlens array of the overcoat layer and has a rectangular shape whose both sides facing along the second diagonal direction have an uneven portion. As a result, the interference fringe of the first and second unit cells UC1 and UC2 is removed due to the destructive interference, and the quality of reflection visibility is improved.

Further, the interference fringes of the first and second unit cells UC1 and UC2 are destructively interfered with each other by adjusting the first refractive index and the first thickness of the phase retardation pattern 954 and the second refractive index of the planarizing layer. As a result, the interference fringe of the first and second unit cells UC1 and UC2 is removed in a relatively wide viewing angle range less than about 70 degrees for the external light of the entire wavelength band, and the quality of reflection visibility is improved.

In addition, since the phase retardation pattern 954 of the rectangular shape is disposed along the first diagonal direction, the interference fringe of the first and second unit cells UC1 and UC2 along a diagonal direction is further removed due to the destructive interference, and the quality of reflection visibility is improved.

Although the OLED display device has a bottom emission type in the first to ninth embodiments, a phase retardation pattern can be formed in a top emission type OLED display device in another embodiment. In a top emission type OLED display device, a phase retardation pattern and a planarizing layer can be disposed on a second electrode of a light emitting diode.

Consequently, in the OLED display device according to embodiments of the present disclosure, the phase retardation pattern is disposed to correspond to one of the first and second unit cells of the microlens array. As a result, the interference fringes generated by the first and second unit cells of the microlens array are offset such that deterioration such as a rainbow stain is minimized and the quality of reflection visibility is improved. Further, the power consumption is reduced such that the OLED display device is driven with a relatively low power.

In addition, the gap length between the first and second unit cells of the microlens array is determined to be smaller than the coherence length and the phase retardation pattern is disposed to correspond to one of the first and second unit cells of the microlens array. As a result, deterioration such as a rainbow stain is minimized in the viewing angle range equal to or smaller than about 70 degrees for the entire wavelength range, and the quality of reflection visibility is improved.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims.

What is claimed is:

1. An organic light emitting diode display device, comprising:
a substrate having a subpixel;
a phase retardation pattern in the subpixel;
a plurality of microlenses on the phase retardation pattern; and
a light emitting diode on the plurality of microlenses,
wherein the plurality of microlenses include a first unit cell and a second unit cell, and
wherein the phase retardation pattern is disposed to correspond to the first unit cell.

2. The organic light emitting diode display device of claim 1, wherein the first and second unit cells are adjacent to each other.

3. The organic light emitting diode display device of claim 1, wherein the plurality of microlenses have a honeycomb shape of a hexagon, and
wherein each of the first and second unit cells includes a first microlens and second to seventh microlenses surrounding the first microlens.

4. The organic light emitting diode display device of claim 3, wherein the phase retardation pattern extends along one of a horizontal direction, a vertical direction and a diagonal direction, and
wherein a width of both sides of the phase retardation pattern along another of the horizontal direction, the vertical direction and the diagonal direction is not constant.

5. The organic light emitting diode display device of claim 3, wherein the phase retardation pattern has a shape of a plurality of rectangles disposed along one of a horizontal direction, a vertical direction and a diagonal direction.

6. The organic light emitting diode display device of claim 1, wherein the plurality of microlenses have a honeycomb shape of a rectangle, and
wherein each of the first and second unit cells includes a first microlens and second to fifth microlenses surrounding the first microlens.

7. The organic light emitting diode display device of claim 6, wherein the phase retardation pattern has a shape of a plurality of rectangles disposed along one of a horizontal direction and a vertical direction.

8. The organic light emitting diode display device of claim 6, wherein the phase retardation pattern extends along a first diagonal direction, and
wherein a width of both sides of the phase retardation pattern along a second diagonal direction crossing the first diagonal direction is not constant.

9. The organic light emitting diode display device of claim 1, wherein a gap length between centers of the first and second unit cells is smaller than a coherence length of an external light.

10. The organic light emitting diode display device of claim 1, further comprising:
a planarizing layer on the phase retardation pattern,
wherein the phase retardation pattern has a first refractive index and a first thickness,
wherein the planarizing layer has a second refractive index, and
wherein the first thickness is determined according to a below equation,
t1=λ/(4*(n1-n2))
where t1: first thickness, λ: wavelength of external light, n1: first refractive index, n2: second refractive index.

11. The organic light emitting diode display device of claim 1, further comprising:
a planarizing layer on the phase retardation pattern; and
an overcoat layer on the planarizing layer,
wherein the plurality of microlenses are disposed on a top surface of the overcoat layer.

12. The organic light emitting diode display device of claim 11, further comprising:
a thin film transistor in the subpixel and connected to the light emitting diode;
a protecting layer disposed between the thin film transistor and the phase retardation pattern;
a passivation layer disposed between the phase retardation pattern and the overcoat layer; and
a face seal and a protecting film on the light emitting diode.

13. The organic light emitting diode display device of claim 1, wherein the phase retardation pattern overlaps the first unit cell and is separated from the second unit cell.

14. The organic light emitting diode display device of claim 1, wherein the first and second unit cells are disposed to contact each other.

15. An organic light emitting diode display device, comprising:
a plurality of subpixels, each of the plurality of subpixels including an emission area and a non-emission area adjacent to the emission area,
wherein each of the plurality of subpixels comprises:
a phase retardation pattern disposed on a substrate and in the emission area;
a plurality of microlenses disposed on the phase retardation pattern and in the emission area; and
a light emitting diode disposed on the plurality of microlenses and in the emission area,
wherein the plurality of microlenses include a first unit cell and a second unit cell adjacent to each other, and
wherein the phase retardation pattern is disposed to correspond only to one of the first unit cell and the second unit cell.
